(19) United States
(12) Patent Application Publication
(10) Pub. No.: US 2025/0292119 A1
(43) Pub. Date: Sep. 18, 2025

(54) RECORDING MEDIUM, INFORMATION PROCESSING APPARATUS, AND INFORMATION PROCESSING METHOD

(71) Applicant: Tokyo Electron Limited, Tokyo (JP)

(72) Inventors: Dai KOBAYASHI, Sapporo City (JP); Jun SHINAGAWA, Fremont, CA (US)

(73) Assignee: Tokyo Electron Limited, Tokyo (JP)

(21) Appl. No.: 19/221,654

(22) Filed: May 29, 2025

Related U.S. Application Data
(63) Continuation of application No. PCT/JP2023/042110, filed on Nov. 24, 2023.
(60) Provisional application No. 63/428,526, filed on Nov. 29, 2022.

(51) Int. Cl. G06N 5/025

(52) U.S. Cl. CPC G06N 5/025

(57) ABSTRACT

A non-transitory computer readable recording medium storing a computer program causing a computer to execute processing of acquiring observation data corresponding to a plurality of types of observable variables from an observation system to be monitored, deriving causal relationships between the observable variables based on the acquired observation data, extracting one or more other observable variables, which are candidates for a cause of a fluctuation in one observable variable, based on the derived causal structure, and outputting a extracted result.

### CROSS-REFERENCE TO RELATED APPLICATIONS

This application is a bypass continuation application of International Application No. PCT/JP2023/042110 having an international filing date of Nov. 24, 2023, and designating the United States, the international application being based upon and claiming the benefit of priority from U.S. Provisional Application No. 63/428,526 filed on Nov. 29, 2022, the entire contents of each are incorporated herein by reference.

### TECHNICAL FIELD

The present disclosure relates to a recording medium, an information processing apparatus, and an information processing method.

### BACKGROUND

In a substrate processing apparatus, a substrate is processed based on a process recipe. The recipe is composed of a plurality of steps, and various parameters, such as pressure and temperature, can be controlled in each step to obtain optimal processing results. Setting values of various parameters may differ for each step. Therefore, measurement data of a plurality of sensors provided in the substrate processing apparatus is managed for each substrate.
Patent Document 1 discloses a technique for visualizing data for a process having multi-dimensional independent variables and dependent variables.
Patent Document 1: Japanese Patent Laid-Open Publication No. 2022-502806

### SUMMARY

An object of the present disclosure is to provide a recording medium, an information processing apparatus, and an information processing method that derive a causal structure between observable variables based on observation data.

According to the present disclosure, there is provided a non-transitory computer readable recording medium storing a computer program causing a computer to execute processing of acquiring observation data corresponding to a plurality of types of observable variables from an observation system to be monitored, deriving causal relationships between the observable variables based on the acquired observation data, extracting one or more other observable variables, which are candidates for a cause of a fluctuation in one observable variable, based on the derived causal structure, and outputting a extracted result.

According to the present disclosure, it is possible to derive a causal structure between observable variables based on observation data.

### BRIEF DESCRIPTION OF DRAWINGS

FIG. 1 is an explanatory view depicting a configuration of an information processing system according to an embodiment.

FIG. 2 is a schematic view depicting an example of a causal structure derived by an information processing apparatus.

FIG. 3 is a block diagram depicting an internal configuration of the information processing apparatus.

FIG. 4 is a directed acyclic graph expressing a relationship between observable variables.

FIG. 5 is a schematic view depicting an example of a directed acyclic graph in which edges are drawn from a plurality of other nodes to one node.

FIG. 6 is a flowchart depicting a procedure of deriving the causal structure.

FIG. 7 is an explanatory view depicting an operation of modifying the causal structure.

FIG. 8 is a flowchart depicting a procedure of modifying the causal structure by a user.

FIG. 9 is a flowchart depicting a procedure of generating a predictive model.

FIG. 10 is a flowchart depicting a procedure of executing quality prediction.

FIG. 11 is an explanatory view depicting a method for estimating a cause of a fluctuation.

FIG. 12 is a flowchart depicting a procedure of estimating the cause of the fluctuation.

FIG. 13 is a flowchart depicting a procedure of outputting countermeasure information.

FIG. 14 is an explanatory view depicting an operation when candidates for the cause of the fluctuation are narrowed down.

FIG. 15 is a flowchart depicting a procedure of receiving an operation of narrowing down the causes of the fluctuation.

FIG. 16 is a flowchart depicting a procedure of deriving a causal structure in Embodiment 7.

FIG. 17 is a schematic view depicting an example of a causal structure in which a function form has been complemented.

FIG. 18 is a schematic view depicting an example of display of a nonlinear relationship as a graph.

FIG. 19 is a schematic view depicting an example of visualization as knowledge of a process mechanism.

FIG. 20 is a schematic view depicting an example of a causal structure used for failure prediction.

FIG. 21 is a flowchart depicting a procedure of creating a process window.

### DETAILED DESCRIPTION

Hereinafter, embodiments will be described with reference to the drawings.

### Embodiment 1

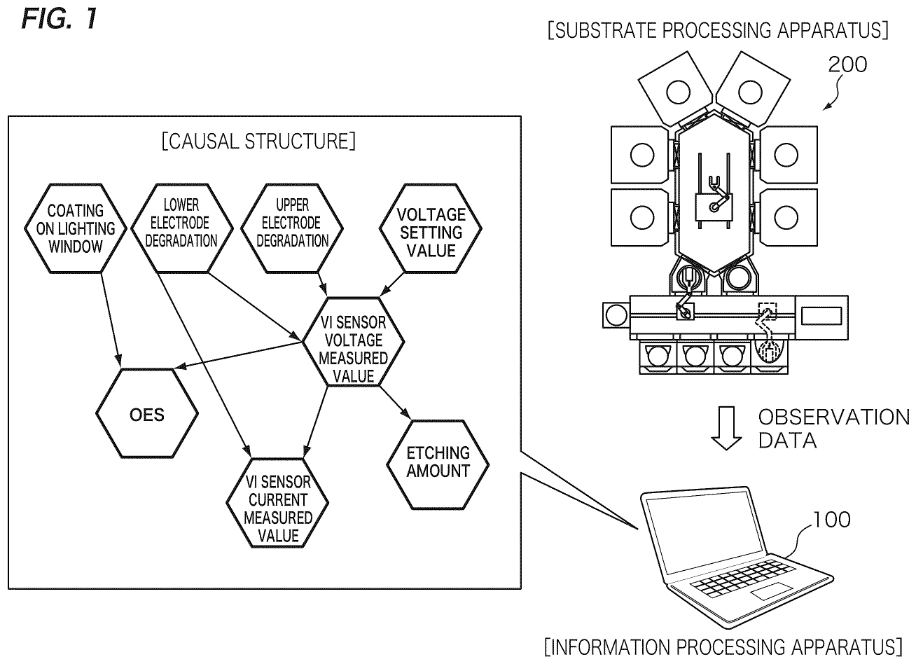

FIG. 1 is an explanatory view depicting a configuration of an information processing system according to an embodiment. The information processing system according to the embodiment includes an information processing apparatus 100 and a substrate processing apparatus 200 that are connected such that they can communicate with each other.

The substrate processing apparatus 200 is, for example, a semiconductor manufacturing apparatus including at least one of an exposure apparatus, an etching apparatus, a film forming apparatus, an ion implantation apparatus, an ashing apparatus, a sputtering apparatus, and the like. Alternatively, the substrate processing apparatus 200 may be a display manufacturing apparatus that manufactures flat display panels (FDPs) such as a liquid crystal display panel and an organic electro-luminescence (EL) panel.

When a process is started, various setting values, such as a substrate temperature, the internal pressure of a chamber, a gas flow rate in the chamber, and a voltage applied by a high-frequency power source, are set in the substrate processing apparatus 200. In addition, the substrate processing apparatus 200 is provided with a plurality of sensors that measure the substrate temperature, the internal pressure of the chamber, the gas flow rate in the chamber, the voltages applied to the upper and lower electrodes, and the like while the process is being executed. The substrate processing apparatus 200 outputs the setting values that are set when the process is started and measured values that are measured while the process is being executed as observation data to the information processing apparatus 100.

The information processing apparatus 100 acquires observation data from an observation system to be monitored (the substrate processing apparatus 200 in this embodiment). The information processing apparatus 100 discovers causal relationships between observable variables, based on the acquired observation data, and modifies the causal relationships according to constraint conditions to be applied between the observable variables to derive a causal structure of all of the observable variables in the observation system.

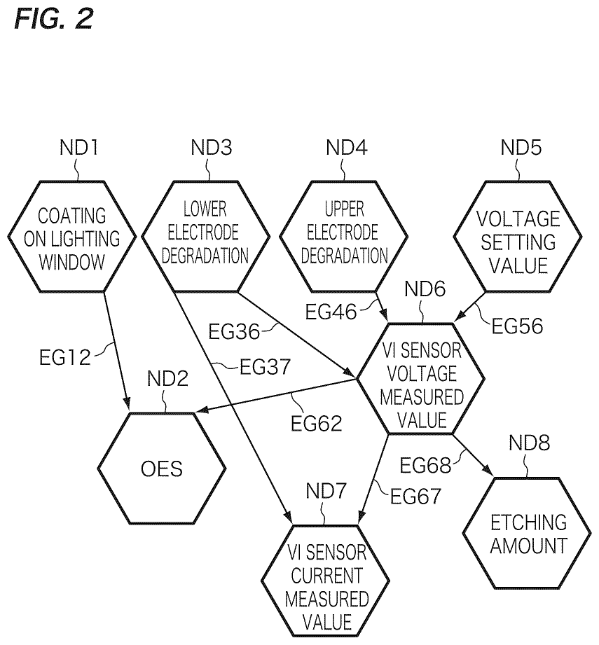

FIG. 2 is a schematic view depicting an example of the causal structure derived by the information processing apparatus 100. The causal structure is drawn, for example, by a directed acyclic graph using nodes indicating observable variables and edges indicating causal relationships between the nodes. In an actual process in the substrate processing apparatus 200, a large number of observable variables are handled. However, for simplicity, FIG. 2 depicts only eight observable variables and the causal structure of these observable variables.

The directed acyclic graph depicted in FIG. 2 is composed of nodes ND1 to ND8 corresponding to the eight observable variables and a plurality of edges EG12, EG36, EG37, EG46, EG56, EG62, EG67, and EG68 indicating the causal relationships between the observable variables (between the nodes). In the example depicted in FIG. 2, the nodes ND1 to ND8 are represented by regular hexagonal icons, but the shape of the icon is not limited to the regular hexagon and may be a circular shape or other shapes. A character string inside the icon indicates the name of each observable variable.

The edge EG12 drawn from the node ND1 to the node ND2 is depicted between the two nodes ND1 and ND2. The edge EG12 connecting the two nodes ND1 and ND2 indicates that there is the causal relationship between the observable variable (coating on a lighting window) corresponding to the node ND1 and the observable variable (OES) corresponding to the node ND2. The coating on the lighting window indicates the amount of coating deposited on a lighting window. OES is an optical emission spectrometer and indicates measurement data of the emission intensity of plasma. The direction of the edge EG12 (the direction represented by an arrow) indicates that the coating on the lighting window has an influence on the OES. The same applies to the causal relationships between the other nodes.

In the following description, when a first observable variable has an influence on a second observable variable, the first observable variable is also referred to as an observable variable disposed on an upstream side of the second observable variable, and the second observable variable is also referred to as an observable variable disposed on a downstream side of the first observable variable.

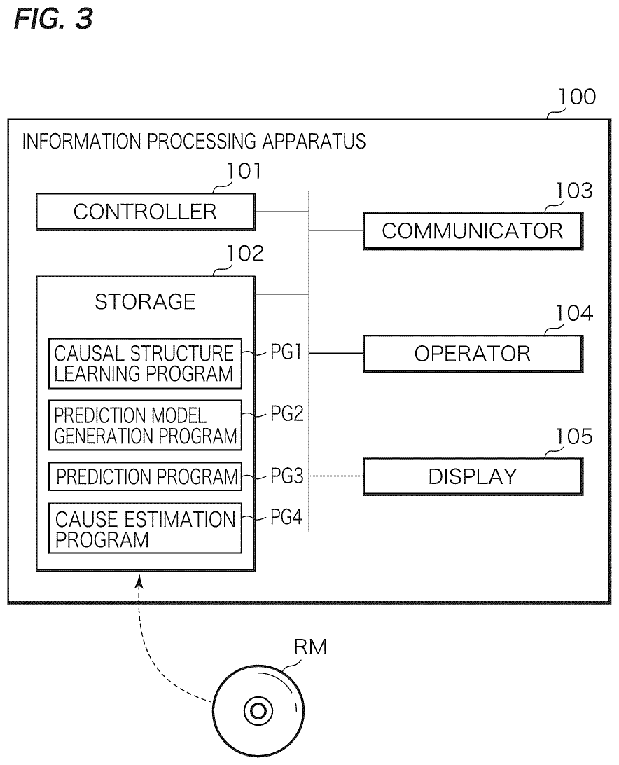

A configuration of the information processing apparatus 100 that derives the causal structure will be described below. FIG. 3 is a block diagram depicting an internal configuration of the information processing apparatus 100. The information processing apparatus 100 is, for example, a dedicated or general-purpose computer including a controller 101, a storage 102, a communicator 103, an operator 104, and a display 105.

The controller 101 includes a central processing unit (CPU), a read only memory (ROM), a random access memory (RAM), and the like. The ROM included in the controller 101 stores, for example, a control program for controlling the operation of each of hardware included in the information processing apparatus 100. The CPU in the controller 101 reads the control program stored in the ROM or a computer program (which will be described below) stored in the storage 102 and executes the program to control the operation of each of the hardware, thereby causing the entire apparatus to function as the information processing apparatus according to the present disclosure. The RAM included in the controller 101 temporarily stores data used during the execution of calculations.

In the embodiment, the controller 101 is configured to include the CPU, the ROM, and the RAM. However, the configuration of the controller 101 is not limited to the above. The controller 101 may be, for example, one or more control circuits, arithmetic circuits, or circuitry including a graphics processing unit (GPU), a field programmable gate array (FPGA), a digital signal processor (DSP), a quantum processor, a volatile or non-volatile memory, and the like. The control unit 11 may be provided as an integrated unit or as a partially separated unit. In addition, the controller 101 may have the functions of a clock that outputs date and time information, a timer that measures the time elapsed from when a measurement start instruction is given to when a measurement end instruction is given, a counter that counts numbers, and the like.

The storage 102 includes a storage apparatus, such as a hard disk drive (HDD), a solid state drive (SSD), or an electronically erasable programmable read only memory (EEPROM). The storage 102 stores various computer programs executed by the controller 101 and various types of data used by the controller 101.

The computer programs (program products) stored in the storage 102 include a causal structure learning program PG1 for causing the computer to execute a process of deriving the causal structure of the observable variables from the observation data of the substrate processing apparatus 200. The causal structure learning program PG1 may be a single computer program or may be composed of a plurality of computer programs. In addition, the causal structure learning program PG1 may be executed by a plurality of computers in cooperation with each other. Further, the causal structure learning program PG1 may partially use an existing library.

The storage 102 may include a prediction model generation program PG2 that generates a prediction model based on the causal relationships between the observable variables, a prediction program PG3 that predicts observation data using the prediction model, and a cause estimation program PG4 that estimates the cause of a fluctuation in the process and recommends countermeasures, in addition to the causal structure learning program PG1. These programs PG1 to PG4 may be independent computer programs or may be integrated into one computer program.

The computer programs including the causal structure learning program PG1 are provided by a non-transitory recording medium RM on which the computer programs are readably recorded. The recording medium RM is a portable memory such as a CD-ROM, a USB memory, a secure digital (SD) card, a micro-SD card, or a Compact Flash (registered trademark) card. The controller 101 reads various computer programs from the recording medium RM, using a reading apparatus which is not depicted in the drawings, and stores the read various computer programs in the storage 102. Furthermore, the computer program stored in the storage 102 may be provided by communication. In this case, the controller 101 may acquire the computer program, using communication via the communicator 103, and store the acquired computer program in the storage 102.

The communicator 103 includes a communication interface for transmitting and receiving various types of data to and from an external apparatus. A communication interface conforming to a communication standard, such as a local area network (LAN), can be used as the communication interface of the communicator 103. The external apparatus is the substrate processing apparatus 200, a user terminal (not depicted), or the like. When data to be transmitted is input from the controller 101, the communicator 103 transmits the data to the destination external apparatus. When data transmitted from the external apparatus is received, the communicator 103 outputs the received data to the controller 101.

The operator 104 includes operation apparatuses, such as a touch panel, a keyboard, and switches, and receives various operations and settings input by the user or the like. The controller 101 performs appropriate control based on various types of operation information given by the operator 104 and stores setting information in the storage 102 as necessary.

The display 105 includes a display apparatus, such as a liquid crystal monitor or an organic electro-luminescence (EL) display, and displays information to be notified to the user or the like in response to an instruction from the controller 101.

In addition, the information processing apparatus 100 according to this embodiment may be a single computer or may be a computer system composed of a plurality of computers and peripheral apparatuses. Further, the information processing apparatus 100 may be a virtual machine whose substance has been virtualized or may be a cloud. Furthermore, in this embodiment, the information processing apparatus 100 and the substrate processing apparatus 200 are described as separate apparatuses. However, the information processing apparatus 100 may be provided in the substrate processing apparatus 200.

A method for deriving the causal structure by the information processing apparatus 100 will be described below.

### (1) Discovery of Causal Relationships

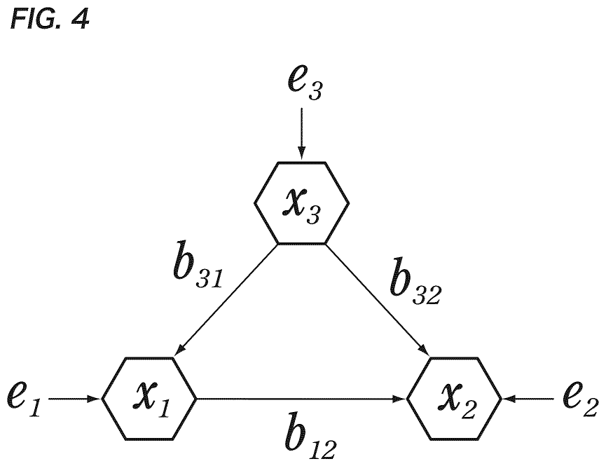

The causal relationships between the observable variables is modeled, for example, by a structural equation model. In a linear non-Gaussian acyclic model (LiNGAM) which is one of the structural equation models, it is assumed that a probability distribution of exogenous variables is a non-Gaussian distribution under a linear acyclic model. Moreover, the relationship between the observable variables is represented by a directed acyclic graph. FIG. 4 is a directed acyclic graph expressing the relationship between the observable variables. In the example depicted in FIG. 4, since the number of observable variables is three, the directed acyclic graph is represented by a 3×3 adjacency matrix B={bᵢⱼ}. bᵢⱼ is a linear regression coefficient and indicates the strength of a connection from an observable variable xⱼ to an observable variable xᵢ. When an exogenous variable (error variable) of the observable variable xⱼ is eⱼ, the structural equation model is represented by Equation 1.

$${x}_{i} = {\sum }_{i \neq j} {b}_{ij} {x}_{j} + {e}_{j} \qquad [ Equation 1 ]$$

A DirectLiNGAM algorithm has been proposed as one of the algorithms (causal discovery algorithms) for discovering the structural equation model (see, for example, S. Shimizu et al. Journal of Machine Learning Research, 12 (April): 1225-1248(2011)). In this algorithm, under the above assumptions, the linear regression coefficient bᵢⱼ can be optimized by repeating regression analysis and the evaluation of the independence of regression residuals. The edge can be drawn between the nodes based on the optimized coefficient bᵢⱼ to draw the directed acyclic graph depicted in FIG. 4.

In the example depicted in FIG. 4, the number of observable variables is three. However, the same applies to a case where the number of observable variables is generalized to n (n is an integer equal to or greater than two). The directed acyclic graph is represented by an n×n adjacency matrix B={bᵢⱼ}.

### (2) Edge Pruning

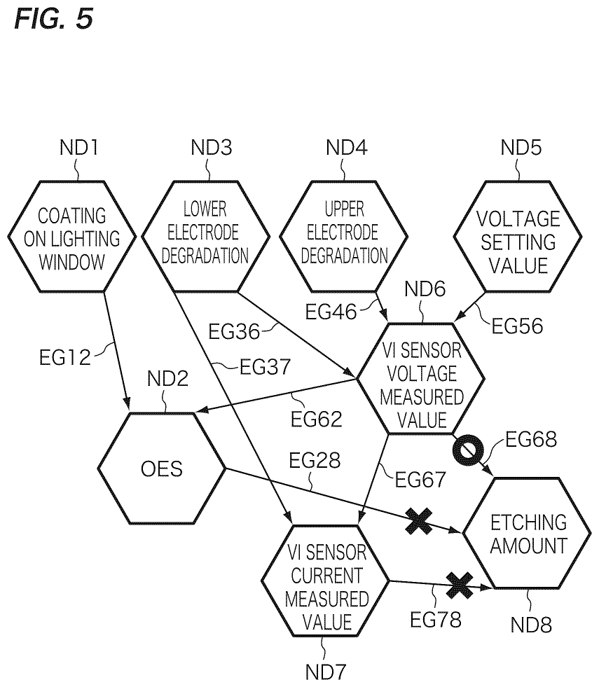

In the above-described causal discovery, the edges may be drawn from a plurality of other nodes to one node as long as the edges are not cyclic. FIG. 5 is a schematic view depicting an example of the directed acyclic graph in which the edges are drawn from a plurality of other nodes to one node. The example depicted in FIG. 5 depicts a case where the edges are drawn from the nodes ND2, ND6, and ND7 that indicate an OES, a VI sensor voltage measured value, and a VI sensor current measured value, respectively, to the node ND8 indicating the amount of etching. This case depicts that the observable variables of the OES, the VI sensor voltage measured value, and the VI sensor current measured value are strongly collinear with each other and are also correlated with the observable variable indicating the amount of etching.

In this embodiment, constraint conditions that prohibit the edges from being drawn from a plurality of observable variables having collinearity to one observable variable at the same time are added in order to avoid this overlearning state. Specifically, it is tested which edge is left for the highest accuracy, and edges other than the edge with the highest accuracy are designated as prohibited edges. In this case, since acyclic constraints also change, a re-discovery of the causal structure is also performed.

The example depicted in FIG. 5 depicts a state in which, among the edges from the nodes ND2, ND6, and ND7 to the node ND8, the edges from the nodes ND2 and ND7 to the node ND8 are designated as the prohibited edges. When the prohibited edges are designated, the acyclic constraints also change. Therefore, the above-described causal discovery algorithm is executed again.

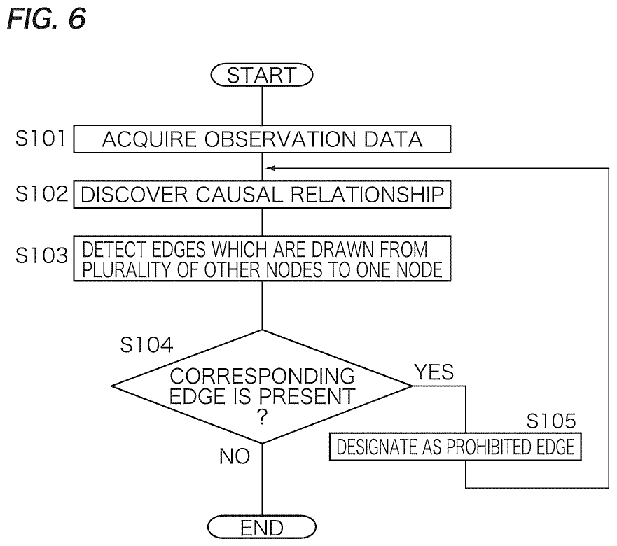

FIG. 6 is a flowchart depicting a procedure of deriving the causal structure. The controller 101 of the information processing apparatus 100 reads the causal structure learning program PG1 from the storage 102 and executes the causal structure learning program PG1 to perform the following processes.

The controller 101 acquires observation data corresponding to a plurality of types of observable variables from the substrate processing apparatus 200 which is the observation system to be monitored (Step S101). The observation data acquired by the controller 101 includes data measured in the substrate processing apparatus 200 and data set in the substrate processing apparatus 200, such as the coating on the lighting window, an OES, degradation of the lower electrode, degradation of the upper electrode, a voltage setting value, the VI sensor voltage measured value, the VI sensor current measured value, and the amount of etching. The controller 101 communicates with the substrate processing apparatus 200 via the communicator 103 to acquire the observation data.

The controller 101 discovers the causal relationships between the observable variables based on the acquired observation data (Step S102). When discovering the causal relationships, as preprocessing, the controller 101 may select the observable variables used to derive the causal structure or may add constraint conditions between the observable variables using prior knowledge of the process in the substrate processing apparatus 200. The controller 101 discovers the causal relationships between the observable variables, using the above-mentioned causal discovery algorithm, to derive the causal structure of all of the observable variables. Specifically, the controller 101 repeats regression analysis and the evaluation of the independence of the regression residuals to optimize the linear regression coefficient bᵢⱼ, assuming that there is linearity between the observable variables, that the causal structure is non-cyclic, that the probability distribution of the exogenous variables is the non-Gaussian distribution, and that different exogenous variables are independent of each other. The controller 101 draws the edges between the nodes, based on the optimized coefficient bᵢⱼ, to generates a directed acyclic graph. In this way, the causal structure between the observable variables, in which the edges from a plurality of nodes having collinearity can be mixed, is obtained.

The controller 101 detects the edges, which have been drawn from a plurality of other nodes having collinearity to one node, from the causal structure obtained in Step S102 (Step S103). The controller 101 determines whether a corresponding edge is present or absent (Step S104). When determining that a corresponding edge is present (S104: YES), the controller 101 designates edges other than the edge with the highest accuracy as the prohibited edges in order to add constraint conditions that prohibit the edges from being drawn from a plurality of observable variables having collinearity to one observable variable at the same time (Step S105), and returns the process to Step S102.

When determining in Step S104 that a corresponding edge is absent (S104: NO), the controller 101 ends the process of this flowchart.

Therefore, the controller 101 can derive the causal structure of all of the observable variables depicted in FIG. 2. The controller 101 may display the derived causal structure on the display 105 or may notify the user terminal (not depicted) of the derived causal structure via the communicator 103.

As described above, in Embodiment 1, it is possible to derive the causal structure of all of the observable variables based on the observation data obtained from the observation system to be monitored (substrate processing apparatus 200) and to present the causal relationships between the observable variables to the user.

In Embodiment 1, since the edge pruning that prevents a plurality of nodes having collinearity from having the causal relationships with another node at the same time is performed, it is possible to prevent erroneous recognition of the edges and to learn the causal structure with higher reliability.

### Embodiment 2

In Embodiment 2, a configuration will be described in which, for a causal structure presented to the user, the causal structure is modified by receiving an interactive operation.

In addition, since an overall configuration of a system and an internal configuration of an information processing apparatus 100 are the same as those in Embodiment 1, a description thereof will be omitted.

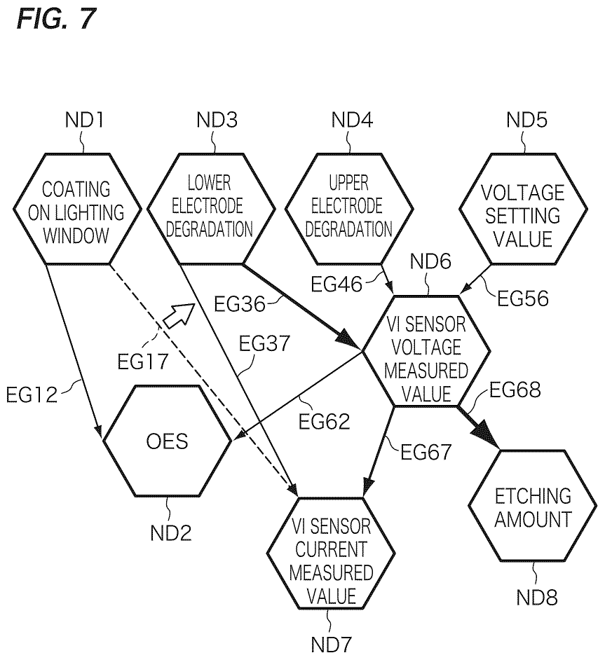

FIG. 7 is an explanatory view depicting an operation of modifying a causal structure. The controller 101 of the information processing apparatus 100 derives a causal structure of all observable variables, using the method disclosed in Embodiment 1, and displays the derived causal structure on the display 105. The causal structure is drawn by a directed acyclic graph. In a process of deriving the causal structure, since the controller 101 calculates a degree of influence (linear regression coefficient bᵢⱼ) of one node on another node, the thickness or color of the edge between the nodes may be changed based on the degree of influence. For example, when the degree of influence of one node on another node is relatively large, the edge connecting the two nodes may be thickened or may be displayed in a color, such as red or blue, different from the colors of other edges.

In the directed acyclic graph depicted in FIG. 7, edges EG36 and EG68 are depicted thicker than other edges, which indicates that the degree of influence of the VI sensor voltage measured value and the degradation of the lower electrode on the amount of etching is larger than that of the degradation of the upper electrode and the voltage setting value.

The controller 101 receives the modification operation of the user on the directed acyclic graph displayed on the display 105 through the operator 104. For example, the controller 101 receives an operation of newly drawing an edge using the mouse or the touch panel provided in the operator 104. This operation enables the user to newly add the edge that should be originally present between any two nodes. In addition, the controller 101 may receive an operation of selecting an edge to be deleted and an operation predetermined to delete the selected edge (for example, an operation of pressing a delete key) using the mouse or the keyboard provided in the operator 104. This operation enables the user to delete an unnecessary edge. Further, the controller 101 may receive an operation of moving a start point or an end point of the edge to another node using the mouse or the touch panel provided in the operator 104. This operation enables the user to change the causal relationships between the observable variables.

FIG. 7 depicts an example in which an operation of moving a start point of an edge EG17 from the node ND1 to the node ND3 is received. In this case, the edge EG17 between the nodes ND1 and ND7 is removed, and a new edge EG7 is generated between the nodes ND3 and ND7. Alternatively, an operation of deleting the edge EG17 and an operation of drawing a new edge (edge EG37) between the nodes ND3 and ND7 may be received.

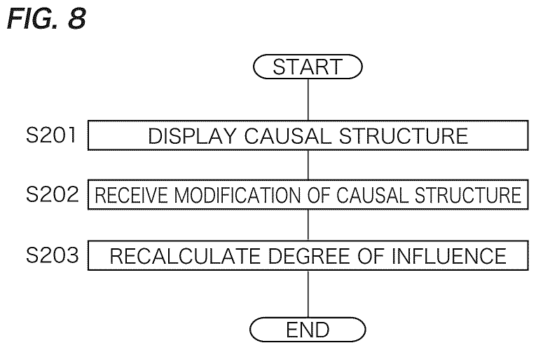

FIG. 8 is a flowchart depicting a procedure of modifying the causal structure by the user. The controller 101 of the information processing apparatus 100 derives a causal structure of all observable variables in the same procedure as in Embodiment 1 and displays the derived causal structure on the display 105 (Step S201). At this time, the thickness or color of the edge may be changed based on the degree of influence of one node on another node, and then the edge may be displayed.

The controller 101 receives the modification of the causal structure displayed on the display 105 through the operator 104 (Step S202). The controller 101 receives, for example, an operation of newly adding the edge that should be originally present, an operation of deleting an unnecessary edge, and an operation of changing the causal relationships through the operator 104.

The controller 101 recalculates the degree of influence based on the modified causal structure (Step S203). Since the degree of influence changes depending on the addition or deletion of the edge, the controller 101 recalculates the degree of influence (linear regression coefficient bᵢⱼ) using Equation 1, without changing the causal structure.

For example, when a sufficient amount of observation data required for learning is not obtained, there is a probability that the causal structure algorithm alone will be insufficient to fully modify the causal relationships between the observable variables. In Embodiment 2, it is possible to delete an erroneous edge and to add a known edge through an interactive operation. It is possible to modify the causal structure based on the user's knowledge.

### Embodiment 3

In Embodiment 3, a configuration will be described in which a prediction model is generated based on the derived causal structure.

In addition, since an overall configuration of a system and an internal configuration of an information processing apparatus 100 are the same as those in Embodiment 1, a description thereof will be omitted.

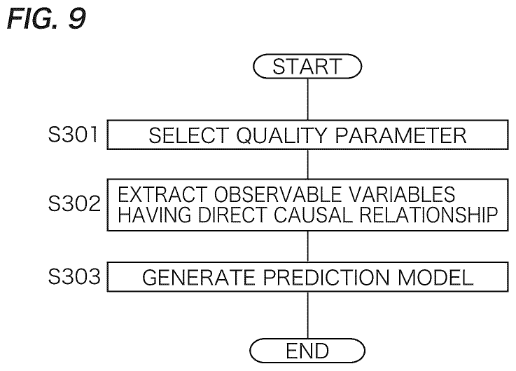

FIG. 9 is a flowchart depicting a procedure of generating a prediction model. The controller 101 of the information processing apparatus 100 reads the prediction model generation program PG2 from the storage 102 and executes the prediction model generation program PG2 to perform the following processes. In addition, it is assumed that the causal structure of the observation system to be monitored has already been derived.

The controller 101 receives a selection of a quality parameter to be monitored (Step S301). Here, one observable variable to be monitored is selected from the causal structure displayed on the display 105.

The controller 101 extracts one or more observable variables having a direct causal relationship with the quality parameter selected in Step S301 (Step S302). For example, when the causal structure depicted in FIG. 2 is the derived causal structure and the amount of etching of the node ND8 is the quality parameter selected in Step S301, the controller 101 extracts the VI sensor voltage measured value of the node ND6 as the observable variable having a direct causal relationship with the amount of etching.

The controller 101 generates a prediction model, using the quality parameter selected in Step S301 as an objective variable and the observable variable selected in Step S302 as an explanatory variable (Step S303). Any model can be used as the prediction model. For example, when a relationship between the quality parameter (=Y) and the observable variable (=x) extracted as the explanatory variable is represented by a linear function, the prediction model can be written as Y=ax+b. Since observation data is obtained for the quality parameter Y and the observable variable x, coefficients a and b can be calculated by optimizing the prediction model using the observation data. The prediction model is not limited to the linear function and may be any function. In addition, the prediction model may be a learning model of machine learning.

As described above, in Embodiment 3, when the quality parameter is designated, the observable variable having a direct causal relationship with the quality parameter can be extracted based on the derived causal structure, and the prediction model that predicts the quality parameter from the observable variable can be generated. That is, in Embodiment 3, parameters corresponding to spurious correlations are eliminated, which makes it possible to generate a prediction model that is robust against factors that may change the results.

Further, in Embodiment 3, the controller 101 extracts the observable variable (explanatory variable) having a direct causal relationship with the quality parameter. However, the user may arbitrarily select an explanatory variable. The user may select a node corresponding to the observable variable to be used as the explanatory variable, using the operator 104, with reference to the causal structure displayed on the display 105. For example, in the causal structure depicted in FIG. 2, when the amount of etching of the node ND8 is set as the quality parameter, the observable variable extracted as the explanatory variable is the VI sensor voltage measured value. However, it is possible to add the observable variable, such as the OES, that does not have a direct causal relationship with the quality parameter to the explanatory variable when the user wishes.

### Embodiment 4

In Embodiment 4, a configuration will be described in which quality is predicted using the generated prediction model.

In addition, since an overall configuration of a system and an internal configuration of an information processing apparatus 100 are the same as those in Embodiment 1, a description thereof will be omitted.

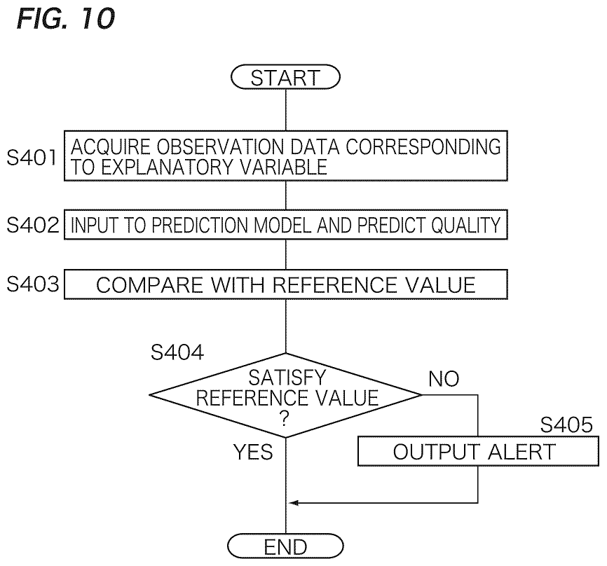

FIG. 10 is a flowchart depicting a procedure of predicting the quality. After generating a prediction model, the controller 101 of the information processing apparatus 100 reads the prediction program PG3 from the storage 102 and executes the prediction program PG3 to perform the following processes.

The controller 101 acquires observation data corresponding to the explanatory variable of the prediction model from the substrate processing apparatus 200 which is the observation system to be monitored (Step S401). When the explanatory variable is the VI sensor voltage measured value, the controller 101 acquires data of the measured voltage value obtained from the VI sensor.

The controller 101 inputs the acquired observation data to the prediction model to predict the quality (Step S402). The controller 101 can execute a calculation using the prediction model to predict the quality.

The controller 101 compares the quality predicted in Step S402 with a reference value (Step S403) and determines whether or not the quality satisfies the reference value (Step S404). When determining that the quality satisfies the reference value (S404: YES), the controller 101 determines that the process being performed in the substrate processing apparatus 200 is normal and ends the process of this flowchart.

On the other hand, when determining that the quality does not satisfy the reference value (S404: NO), the controller 101 determines that the process being performed in the substrate processing apparatus 200 is not normal, outputs an alert (Step S405), and ends the process of this flowchart. For example, the controller 101 displays information indicating that the process is not normal on the display 105 to output the alert. Alternatively, the controller 101 may notify the user terminal (not depicted) of the information indicating that the process is not normal via the communicator 103.

As described above, in Embodiment 4, the quality is predicted using the prediction model, and it is determined whether or not the predicted quality satisfies the reference value. Therefore, it is possible to determine whether or not the process being performed in the substrate processing apparatus 200 is normal.

### Embodiment 5

In Embodiment 5, a configuration will be described in which a cause of a fluctuation in one observable variable is estimated based on a causal structure.

In addition, since an overall configuration of a system and an internal configuration of an information processing apparatus 100 are the same as those in Embodiment 1, a description thereof will be omitted.

In Embodiment 5, for the observable variable whose fluctuation cause is unknown, the upstream side of the fluctuating observable variable is checked, using the derived causal structure, to specify the cause of the fluctuation.

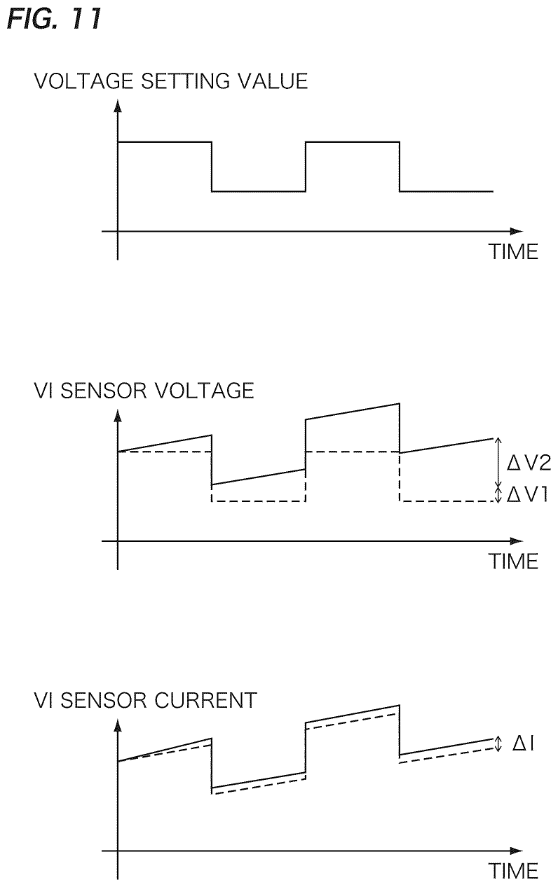

FIG. 11 is an explanatory view depicting a method for estimating the cause of the fluctuation. It is assumed that the causal structure depicted in FIG. 2 is obtained as the causal structure of the observable variables. The causal structure depicts that the observable variables influencing the VI sensor voltage measured value of the node ND6 are the degradation of the lower electrode of the node ND3, the degradation of the upper electrode of the node ND4, and the voltage setting value of the node ND5. In addition, the causal structure depicts that the observable variables influencing the VI sensor current measured value of the node ND7 are the degradation of the lower electrode of the node ND3 and the VI sensor voltage measured value of ND6.

The VI sensor voltage measured value and the VI sensor current measured value are represented by the following calculation expressions.

$$V I sensor voltage measure value = w 1 \times voltage setting value + w 2 \times degradation of lower electrode + w 3 \times degradation of upper electrode$$

$$V I sensor current measured value = w 4 \times measured voltage value of V I sensor + w 5 \times degradation of lower electrode$$

Here, w1 to w5 are coefficients represented by the degree of influence of the edge.

In FIG. 11, an upper part depicts a fluctuation in the voltage setting value over time, a middle part depicts a fluctuation in the VI sensor voltage measured value over time, and a lower part depicts a fluctuation in the VI sensor current measured value over time. When there is no degradation of the lower electrode and the upper electrode, the VI sensor voltage measured value can be explained only by the voltage setting value and thus should fluctuate as represented by a dashed line in the middle graph. However, when the actually measured value fluctuates as represented by a solid line, it is presumed that the VI sensor voltage measured value is influenced by the degradation of the lower electrode and the upper electrode. That is, it is presumed that a difference between the graph represented by the dashed line and the graph represented by the solid line includes a difference ΔV1 caused by the lower electrode and a difference ΔV2 caused by the degradation of the lower electrode in the middle graph.

Similarly, when there is no degradation of the lower electrode, the VI sensor current measured value can be explained only by the VI sensor voltage measured value and thus should fluctuate as represented by the dashed line in the lower graph. However, when the actually measured value fluctuates as represented by the solid line, it is presumed that the VI sensor current measured value is influenced by the degradation of the lower electrode. That is, it is presumed that a difference between the graph represented by the dashed line and the graph represented by the solid line includes a difference ΔI caused by the lower electrode in the lower graph.

The controller 101 can estimate the degrees of degradation of the lower electrode and the upper electrode by performing optimization such that the estimation results of the VI sensor voltage measured value and VI sensor current measured value are matched with the actually measured values.

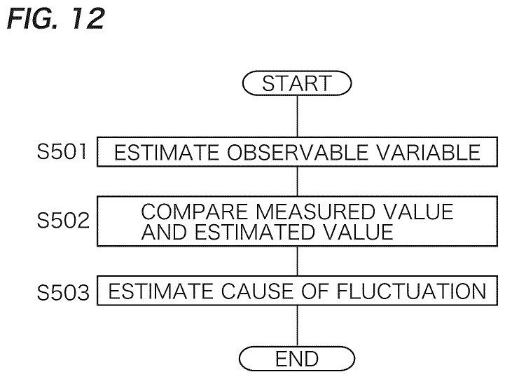

FIG. 12 is a flowchart depicting a procedure of estimating the cause of the fluctuation. After deriving the causal structure, the controller 101 of the information processing apparatus 100 reads the cause estimation program PG4 from the storage 102 and executes the cause estimation program PG4 to perform the following processes.

The controller 101 assumes that there is no cause of fluctuation and performs regression based on the degree of influence of the edge to estimate each observable variable (Step S501).

The controller 101 compares the actually measured value and the estimated value of the observable variable (Step S502). An observable variable having a large difference between the actually measured value and the estimated value can be regarded as having fluctuated due to the intervention of a fluctuation causal factor.

The controller 101 optimizes the degree of fluctuation of the cause of the fluctuation so as to eliminate the difference between the actually measured value and the estimated value and estimates a cause with a relatively large optimized degree of fluctuation as the cause of the fluctuation (Step S503).

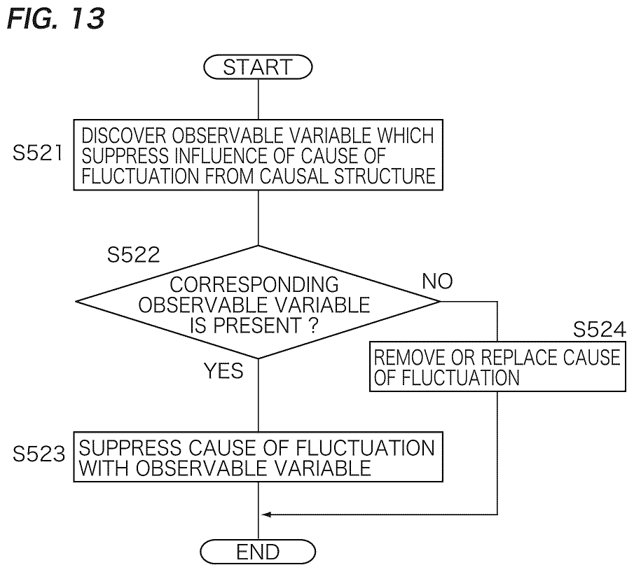

FIG. 13 is a flowchart depicting a procedure of outputting countermeasure information. After estimating the cause of the fluctuation, the controller 101 executes the following processes as necessary.

The controller 101 discovers an observable variable capable of suppressing the influence of the cause of the fluctuation from the causal structure (Step S521) and determines whether a corresponding observable variable is present or absent (Step S522).

When a variable (for example, the voltage setting value) that can be controlled by the substrate processing apparatus 200 is discovered, the controller 101 determines that a corresponding observable variable is present (S522: YES) and outputs the suppression of the cause of the fluctuation with the observable variable as the countermeasure information (Step S523). The countermeasure information is displayed on the display 105. Alternatively, the user terminal is notified of the countermeasure information via the communicator 103.

When the variable (for example, the degradation of the lower electrode or the upper electrode) that can be controlled by the substrate processing apparatus 200 is discovered, the controller 101 determines that a corresponding observable variable is absent (S522: NO) and outputs the removal or replacement of the cause of the fluctuation as the countermeasure information (step S524). The countermeasure information is displayed on the display 105. Alternatively, the user terminal is notified of the countermeasure information via the communicator 103.

As described above, in Embodiment 5, it is possible to estimate the cause of the fluctuation in one observable variable and to present the information of countermeasures against the cause of the fluctuation to the user.

### Embodiment 6

In Embodiment 6, a configuration will be described in which the cause of the fluctuation is estimated based on the user's knowledge.

In addition, since an overall configuration of a system and an internal configuration of an information processing apparatus 100 are the same as those in Embodiment 1, a description thereof will be omitted.

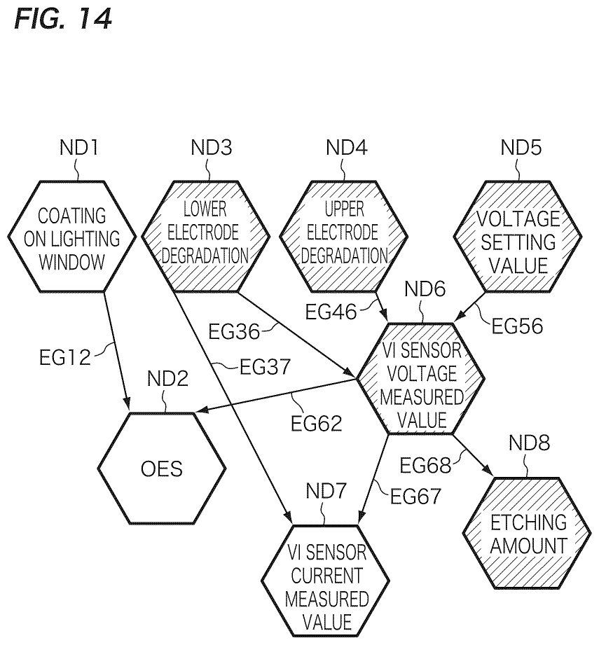

FIG. 14 is an explanatory view depicting an operation when candidates for the cause of the fluctuation are narrowed down. It is assumed that the causal structure depicted in FIG. 14 is obtained and the cause of the fluctuation in the amount of etching of the node ND8 is investigated. In this case, the node ND6 (VI sensor voltage measured value) on the upstream side of the node ND8, and ND3 (the degradation of the lower electrode), ND4 (the degradation of the upper electrode), and ND5 (voltage setting value) on the upstream side of the node ND6 are the candidates for the cause of the fluctuation. For example, the controller 101 of the information processing apparatus 100 changes the colors of the nodes ND3, ND4, ND5, ND6, and ND8 and displays the nodes on the display 105. Instead of the configuration of changing the colors of the nodes, the display manner of the candidates for the cause of the fluctuation may be changed by changing the sizes of the nodes or the thickness of the edges connecting the nodes.

The controller 101 receives an operation of narrowing down the candidates for the cause of the fluctuation from the user through the operator 104. The user can check the observation data obtained for the candidates for the cause of the fluctuation with reference to the causal structure displayed on the display 105 to efficiently narrow down the possibilities. For example, when the relationship between the VI sensor voltage measured value and the amount of etching is normal, the VI sensor voltage measured value can be excluded from the candidates for the cause of the fluctuation. When receiving a selection operation (for example, a click operation) on the node ND6, the controller 101 excludes the VI sensor voltage measured value of the node ND6 from the candidates for the cause of the fluctuation and returns the display manner of the node ND6 to the original state.

A fluctuation in the observable variable on the downstream side of the candidate may be verified in order to further narrow down the candidates for the cause of the fluctuation. For example, in order to verify the influence of the degradation of the lower electrode of the node ND3, the VI sensor voltage measured value of ND6 and the VI sensor current measured value of the node ND7 may be checked to verify the influence of the degradation of the lower electrode. At this time, when the relationship between the VI sensor voltage measured value and the VI sensor current measured value is normal, the degradation of the lower electrode can be excluded from the candidates for the cause of the fluctuation. When receiving a selection operation (for example, a click operation) on the node ND3, the controller 101 excludes the degradation of the lower electrode of the node ND3 from the candidates for the cause of the fluctuation and returns the display manner of the node ND3 to the original state.

As described above, since the candidates for the cause of the fluctuation are narrowed down to two observable variables of the degradation of the upper electrode of ND4 and the voltage setting value of ND5, the controller 101 outputs information prompting the replacement of the upper electrode as the countermeasure information. In addition, the controller 101 outputs information prompting the adjustment of the voltage setting value as the countermeasure information.

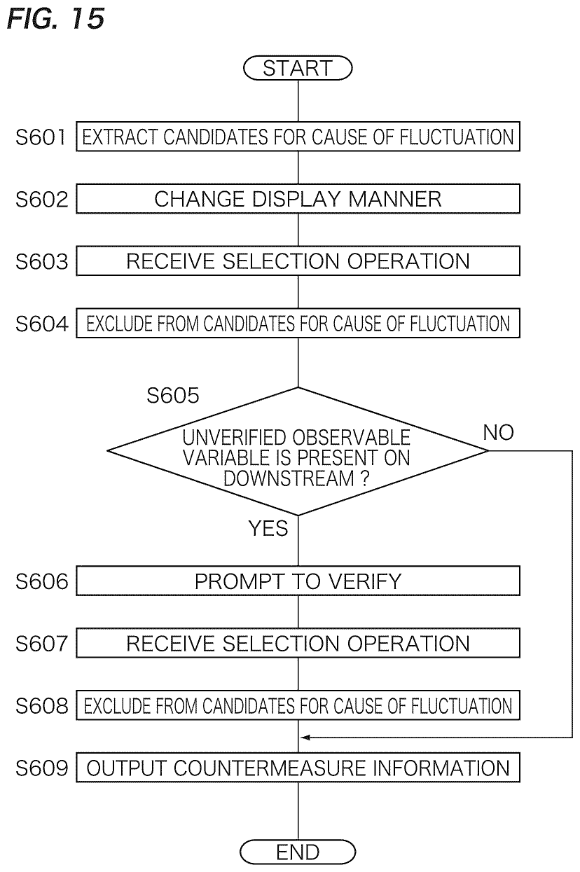

FIG. 15 is a flowchart depicting a procedure of receiving the operation of narrowing down the cause of the fluctuation. After deriving the causal structure, the controller 101 of the information processing apparatus 100 reads the cause estimation program PG4 from the storage 102 and executes the cause estimation program PG4 to perform the following processes.

The controller 101 extracts one or more observable variables, which are candidates for the cause of the fluctuation, for one observable variable designated by the user (Step S601). The controller 101 changes the display manner of the node corresponding to the extracted observable variable (Step S602). The controller 101 may change the display manner of the node corresponding to one observable variable designated by the user in the same manner.

The controller 101 receives a selection operation of selecting an observable variable to be excluded from the candidates for the cause of the fluctuation through the operator 104 (Step S603) and excludes the selected observable variable from the candidates for the cause of the fluctuation (Step S604). In Steps S603 and S604, the observable variable that has been determined to have no problems by the user as the result of the verification and the observable variable that is not related based on the user's knowledge are excluded from the candidates for the cause of the fluctuation. When an observable variable is present further upstream, the processes in Steps S603 and S604 are repeatedly executed.

The controller 101 determines whether an unverified observable variable is present or absent on the downstream side of the candidates for the cause of the fluctuation (Step S605). When an unverified observable variable is present (S605: YES), the controller 101 prompts the user to verify the observable variable (Step S606). The user checks a fluctuation in the downstream observable variable. When there is no fluctuation, the user excludes the observable variable from the candidates for the cause of the fluctuation. That is, the controller 101 receives a selection operation of selecting the observable variable to be excluded from the candidates for the cause of the fluctuation through the operator 104 (Step S607) and excludes the selected observable variable from the candidates for the cause of the fluctuation (Step S608). When determining in Step S605 that an unverified observable variable is absent on the downstream side (S605: NO), the controller 101 advances the process to Step S609.

The controller 101 outputs the countermeasure information based on the candidates for the cause of the fluctuation narrowed down in the procedure of Steps S603 to S608 (Step S609). The countermeasure information is displayed on the display 105. Alternatively, the user terminal is notified of the countermeasure information via the communicator 103.

As described above, in Embodiment 6, it is possible to narrow down the candidates for the cause of the fluctuation based on the user's verification or knowledge. In addition, it is possible to present the countermeasure information to the user based on the narrowed-down candidates for the cause of the fluctuation.

### Embodiment 7

In Embodiment 7, an example of application to a nonlinear system will be described.

In addition, since an overall configuration of a system and an internal configuration of an information processing apparatus 100 are the same as those in Embodiment 1, a description thereof will be omitted.

For linear systems, a highly explanatory and robust prediction model or a reliable abnormal cause specification model can be constructed by performing the selection of features and the learning of the causal structure to narrow down the explanatory variables.

On the other hand, for nonlinear systems, a prediction model is often constructed with random forest or Gaussian process regression, using configuration parameters as the explanatory variables and outcome parameters as the objective variables. In the nonlinear systems, it is difficult to specify a causal structure and a function form, and the model becomes a black box. Therefore, there is a lack of explanatory nature as to how each explanatory variable affects the variation in the objective variable, and it is not possible to finely adjust the setting values or to reliably modify a fluctuation in the result. Further, even when a partial function form is known in advance as domain knowledge, it is not possible to make corrections or constraints based on the partial function form. Therefore, it is difficult to create a model, in which the partial function form or the domain knowledge has been reflected, using only statistical approaches.

In Embodiment 7, a method will be described which learns the causal structure using a method that does not specify an exact function form for parameters having a nonlinear causal relationships therebetween, but can specify whether or not there is a relationship.

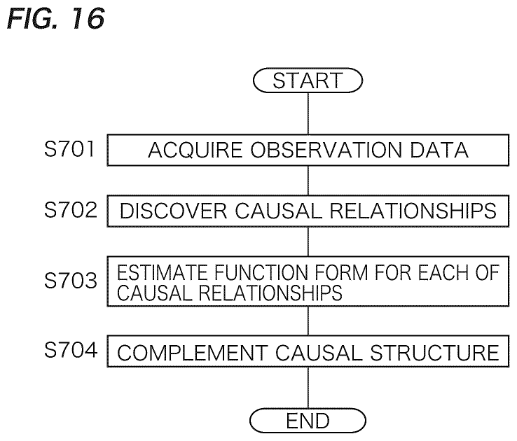

FIG. 16 is a flowchart depicting a procedure of deriving a causal structure in Embodiment 7. The controller 101 of the information processing apparatus 100 reads the causal structure learning program PG1 from the storage 102 and executes the causal structure learning program PG1 to perform the following processes.

The controller 101 acquires observation data corresponding to a plurality of types of observable variables from the substrate processing apparatus 200 which is the observation system to be monitored (Step S701). The observation data acquired by the controller 101 includes data measured in the substrate processing apparatus 200 and data set in the substrate processing apparatus 200. The controller 101 communicates with the substrate processing apparatus 200 via the communicator 103 to acquire the observation data.

The controller 101 discovers the causal relationships between the observable variables based on the acquired observation data (Step S702). When discovering the causal relationships, as preprocessing, the controller 101 may select the observable variables used to derive the causal structure or may add constraint conditions between the observable variables using prior knowledge of the process in the substrate processing apparatus 200. The function form is unknown, but an algorithm capable of performing discovery including nonlinearity is known. Therefore, the controller 101 discovers the causal relationships between the observable variables, using the algorithm, to derive the causal structure of all of the observable variables. After deriving the causal structure, the controller 101 may detect the edges drawn from a plurality of other nodes having collinearity to one node in the same procedure as in Embodiment 1 and may designate edges other than the edge with the highest accuracy as the prohibited edges.

The controller 101 estimates a function form for each of causal relationships (Step S703). At this time, the controller 101 may estimate the function form based on the constraints and knowledge of the domain of the substrate processing apparatus 200.

The controller 101 introduces the estimated function form into the causal structure derived in Step S702 to complement the causal structure (Step S704). The derived causal structure may be displayed on the display 105, or the user terminal (not depicted) may be notified of the derived causal structure via the communicator 103.

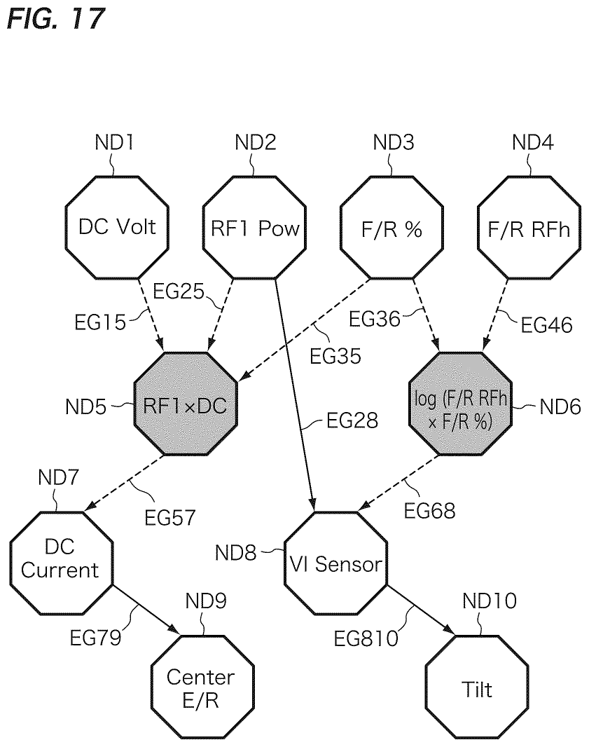

FIG. 17 is a schematic view depicting an example of the causal structure in which the functional forms have been complemented. As in Embodiment 1, the causal structure is drawn by a directed acyclic graph using the nodes indicating the observable variables and the edges indicating the causal relationships between the nodes. FIG. 17 depicts the causal structure in which, for simplification, only eight observable variables are extracted and the functional forms between the observable variables have been complemented.

The directed acyclic graph depicted in FIG. 17 is composed of nodes ND1 to ND4 and ND7 to ND10 corresponding to the eight observable variables, nodes ND5 and ND6 corresponding to two functions, and edges EG15, EG25, EG28, EG35, EG36, EG46, EG57, EG68, EG79, and EG810 indicating the causal relationships between the nodes. In the example depicted in FIG. 17, the nodes ND1 to ND10 are represented by regular octagonal icons. However, the shape of the icon is not limited to the regular octagon and may be a circular shape or other shapes. A character string inside the icon indicates the name of each observable variable or a function form.

In the example depicted in FIG. 17, the nodes ND1 to ND4 and ND7 to ND10 indicating the observable variables and the nodes ND5 and ND6 indicating the functions are depicted in different colors. Alternatively, the icons may be displayed in a different display manner. For example, the icons are displayed in different shapes. Further, in the example depicted in FIG. 17, the edge between the observable variables is represented by a solid line, and the edges indicating an input to the function and an output from the function are represented by dashed lines. Alternatively, the edges may be displayed in a different display manner. For example, the edges are displayed in different colors. Moreover, the nodes of the setting value and the observable value may be displayed in a different display manner such that they can be distinguished from each other.

As described above, in Embodiment 7, it is possible to derive the causal structure that takes into account the nonlinearity between the observable variables, based on observation data obtained from the observation system to be monitored (the substrate processing apparatus 200) and to present the causal structure to the user.

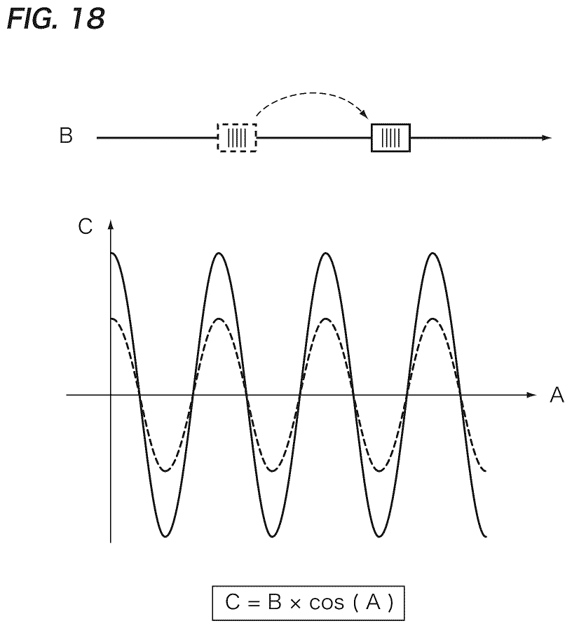

In addition, in Embodiment 7, the node indicating the function form is introduced into the directed acyclic graph to visualize the nonlinear relationship. However, the nonlinear relationship may be displayed as a graph. FIG. 18 is a schematic view depicting an example of the display of the nonlinear relationship as a graph. FIG. 18 depicts an example of display when a relationship between observable variables A, B, and C is C=B×cos(A). FIG. 18 depicts that the value of the observable variable A is fixed and how the observable variable C fluctuates as the value of the observable variable B is moved by a slider.

### Embodiment 8

In Embodiment 8, a configuration will be described in which a causal structure learned from experimental data is visualized as knowledge during process development.

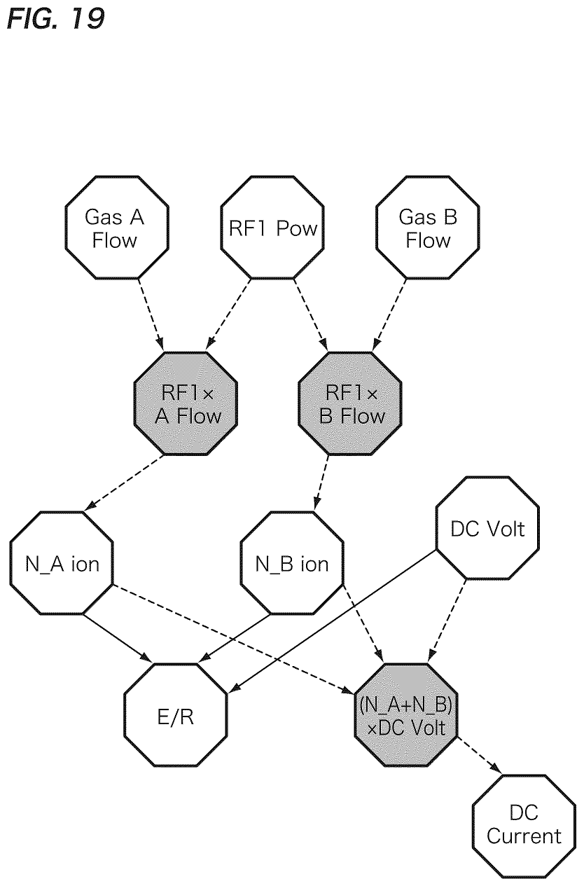

FIG. 19 is a schematic view depicting an example in which the causal structure is visualized as knowledge of a process mechanism. FIG. 19 depicts an example in which the relationships between a flow rate of gas A (Gas A Flow), a flow rate of gas B (Gas B Flow), and RF power (RF1 Pow) and an etching rate (E/R) are visualized as the causal relationships between the observable variables. It is difficult to know the appropriate amount of fluctuation in gas flow rate, RF power, DC bias, and the like even for the etching rate alone, and it is difficult to determine the amount of deviation without referring to comprehensive knowledge including sensors. Therefore, the causal structure is created using the same method as that depicted in FIG. 7, based on the observation data obtained from the experiments, and is visualized as depicted in FIG. 19, which makes it possible to leave the relationship between features so as to be easily referred to and utilized as knowledge.

As described above, in Embodiment 8, since knowledge is left in the form of the causal structure, it is possible to leave knowledge in a form that can be expanded by people other than experts. In addition, since the observable variables and the function forms are formalized and visualized into the causal structure, knowledge can be obtained on how to change the setting values in experiments or on how to get closer to the desired quality.

### Embodiment 9

In Embodiment 9, a configuration will be described in which the entire process is comprehensively predicted to foreknow and prevent failures and abnormalities.

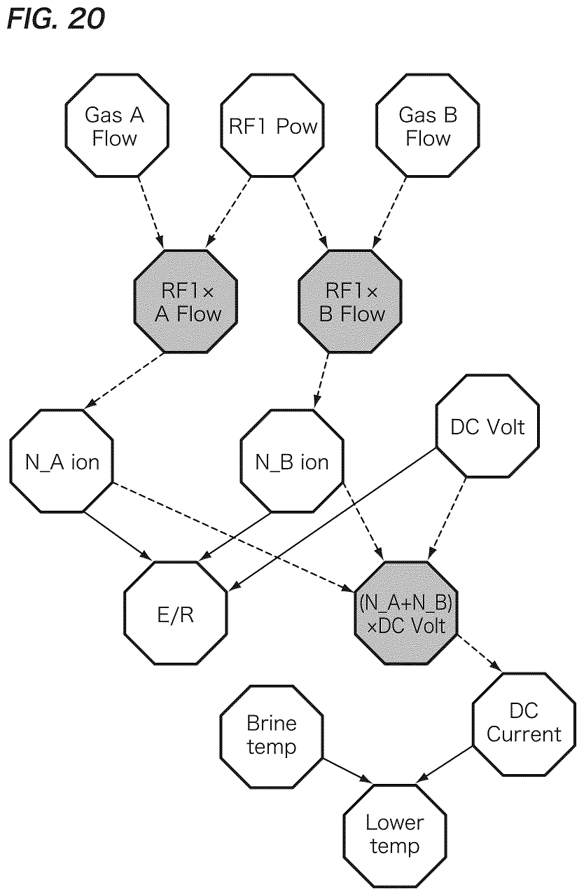

FIG. 20 is a schematic view depicting an example of a causal structure used for failure prediction. In the causal structure depicted in FIG. 20, a DC current (DC Current) and a lower electrode temperature (Lower temp) are not capable of being directly designated only by restricting the setting values of a DC voltage (DC Volt) and a cooling temperature (Brine temp). For example, the etching rate (E/R) is expected to be improved with an increase in plasma flow rate or energy. On the other hand, an increase in electrode temperature is expected. Therefore, when the DC voltage is increased to its limit, there is a concern that the electrodes will be damaged due to overheating.

For this reason, it is necessary to take an overview of the entire process and to determine whether there are any points where sensor values indicate anomalies in light of the causal structure. That is, it is possible to avoid overlooking the risk of failure by taking an overall view rather than making predictions limited to each part.

Specifically, the controller 101 may create a table of processable ranges (process windows) based on the causal structure and present the table to the user. When the process is out of the process window, the controller 101 may suggest an alternative recipe that would fit within the window with minimal modifications.

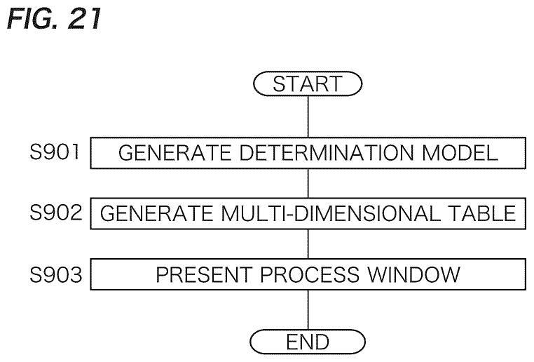

FIG. 21 is a flowchart depicting a procedure of creating a process window. The controller 101 creates a causal structure, in which a function form has been complemented for a nonlinear relationship, in the same procedure as in Embodiment 7 and generates a determination model indicating whether or not the sensor value falls within an allowable range, based on the created causal structure (Step S901).

The controller 101 generates a multi-dimensional table indicating possible ranges for dynamic setting values, using the generated determination model (Step S902). For example, when a table (two-dimensional table) related to two setting values of RF power 1 and RF power 2 is generated, the table depicting that a combination of the two setting values (RF power 1 and RF power 2) is not possible when it is (1000 V, 100 V), is possible when it is (1000 V, 200 V), . . . may be generated.

The controller 101 presents a process window corresponding to the setting of a fixed value, based on the generated multi-dimensional table (Step S903). For example, RF power 1 (or RF power 2) may be fixed, and the range of RF power 2 (or RF power 1) may be generated as the process window and displayed on the display 105.

As described above, in Embodiment 9, it is possible to prevent failures caused by secondary effects during experiments.

The matters described in each embodiment can be combined with each other. In addition, the independent and dependent claims described in the claims can be combined with each other in any and all combinations, regardless of the citation form. The claims may be described in a format in which a claim refers to two or more other claims (multiple claim format). Also the claims may be described in a format in which a multiple dependent claim (multi-multi claim) refers to at least one multiple dependent claim.

The embodiments of the present disclosure are to be considered in all respects as illustrative and not restrictive. The scope of the present invention is defined by the claims, not by the above meaning, and is intended to include all modifications within the meaning and scope of equivalency of the claims.

For example, in the embodiment, the substrate processing apparatus 200 is given as an example of the observation system to be monitored. The observation system to be monitored is not limited to the substrate processing apparatus 200, but may be a manufacturing apparatus in which any manufacturing process of electric equipment, chemical industrial products, pharmaceuticals, food, chemical industrial products, and the like is executed. Furthermore, the observation system to be monitored is not limited to the apparatus or the system in which any manufacturing process is executed, but may be any system which is an appropriate combination of human living environments, economic activities, meteorological environments, and the like.

1. A non-transitory computer readable recording medium storing a computer program causing a computer to execute processing of:
acquiring observation data corresponding to a plurality of types of observable variables from an observation system to be monitored;
deriving causal relationships between the observable variables based on the acquired observation data;
extracting one or more other observable variables, which are candidates for a cause of a fluctuation in one observable variable, based on the derived causal structure; and
outputting a extracted result.

2. The non-transitory computer readable recording medium according to claim 1, storing the computer program causing the computer to execute processing of:
generating a directed acyclic graph expressing the causal structure, using nodes indicating observable variables and edges indicating causal relationships between the nodes; and
displaying the generated directed acyclic graph.

3. The non-transitory computer readable recording medium according to claim 1, storing the computer program causing the computer to execute processing of:
changing a display manner of nodes corresponding to the extracted one or more other observable variables;
receiving an operation of narrowing down the candidates for the cause of the fluctuation from the nodes whose display manner has been changed; and
outputting countermeasure information for suppressing the fluctuation in the one observable variable, based on the narrowed-down candidates for the cause of the fluctuation.

4. The non-transitory computer readable recording medium according to claim 1, wherein a part of the relationships between the observable variables have nonlinearity.

5. The non-transitory computer readable recording medium according to claim 4, storing the computer program causing the computer to execute processing of:
complementing a node, which indicates a function form of a relationship between the observable variables, between the observable variables having the nonlinearity.

6. The non-transitory computer readable recording medium according to claim 4, storing the computer program causing the computer to execute processing of:
displaying the node between the observable variables having the linearity and the node between the observable variables having the nonlinearity in different display manners.

7. The non-transitory computer readable recording medium according to claim 5, storing the computer program causing the computer to execute processing of:
displaying the relationship between the observable variables having the nonlinearity as a graph.

8. An information processing apparatus comprising:
a processor; and
a storage storing instructions causing the processor to execute processing of:
acquiring observation data corresponding to a plurality of types of observable variables from an observation system to be monitored;
deriving causal relationships between the observable variables based on the acquired observation data;
extracting one or more other observable variables, which are candidates for a cause of a fluctuation in one observable variable, based on the derived causal structure; and
outputting a extracted result.

9. An information processing method executed by a computer, the information processing method comprising a process of:
acquiring observation data corresponding to a plurality of types of observable variables from an observation system to be monitored;
deriving causal relationships between the observable variables based on the acquired observation data;
extracting one or more other observable variables, which are candidates for a cause of a fluctuation in one observable variable, based on the derived causal structure; and
outputting a extracted result.
